(19) United States
(12) Patent Application Publication
(10) Pub. No.: US 2022/0221917 A1
(43) Pub. Date: Jul. 14, 2022

(54) CHASSIS COMPONENTS

(71) Applicant: Hewlett-Packard Development Company, L.P., Spring, TX (US)

(72) Inventors: Hung-Wen Chang, Taipei City (TW); Ai-Tsung Li, Taipei City (TW); Hao-Wu Yang, Taipei City (TW); Chien-Tu Cheng, Taipei City (TW); Shih-Han Chen, Taipei City (TW)

(73) Assignee: Hewlett-Packard Development Company, L.P., Spring, TX (US)

(21) Appl. No.: 17/615,344

(22) PCT Filed: Sep. 19, 2019
(86) PCT No.: PCT/US2019/051804

§ 371 Date: Nov. 30, 2021

(51) Int. Cl. G06F 1/20; H05K 7/20

(52) U.S. Cl. CPC G06F 1/20; G06F 2200/201; H05K 7/2029

(57) ABSTRACT

Examples of a chassis component are described herein. In an example, the chassis component can have a recess having a mesh structure and a working fluid disposed therein. A conductive cover can seal the recess with the mesh structure and the working fluid therein.

### BACKGROUND

An electronic device, such as a personal computer (PC), a tablet PC, and a mobile phone, may heat up during operation due to heating up of components, such as a battery or a motherboard. The heating of the electronic device may become more pronounced in recent electronic devices which have a slim form factor and considerably high-speed performance. High-speed performance of the electronic device, usually, leads to considerably high surface temperatures of the electronic device. Such high temperatures of the electronic device may adversely affect operation of the electronic device and, accordingly, the heat has to be carried away from the electronic device.

### BRIEF DESCRIPTION OF FIGURES

The detailed description is provided with reference to the accompanying figures, wherein:

FIG. 1 illustrates a schematic of an electronic device having a chassis component, according to an example;

FIG. 2 illustrates a schematic of the chassis component, according to another example;

FIG. 3 illustrates a cross-sectional view of the chassis component, in accordance with an example;

FIG. 4 illustrates a method of manufacturing the chassis component 102 for the electronic device, according to another example.

It should be noted that the description and the figures are merely examples of the present subject matter and are not meant to represent the subject matter itself. Throughout the drawings, identical reference numbers designate similar, but not identical, elements. The figures are not to scale, and the size of some parts may be exaggerated to more clearly illustrate the example shown. Moreover, the drawings provide examples and/or examples consistent with the description; however, the description is not limited to the examples and/or examples provided in the drawings.

### DETAILED DESCRIPTION

Generally, various provisions may be made in electronic devices, for example, high performance electronic devices, to enable the electronic devices to dissipate the heat. For instance, high performance electronic devices may involve high power consumption by the processor and also heating up of battery during operation. The provisions to dissipate may include, for example, in one case, providing conductive material, such as graphite sheets, on an inside of a body of the electronic device to spread and remove the heat from the components. For adequate performance, the sheets of conductive material have to be attached on the inner surface of the electronic device without bends or creases. However, given the form and design of the body, the sheets of conductive material may not be accommodated in a manner that there are no bends or creases in the sheets, thereby adversely affecting the performance of the sheets.

Examples of chassis components, for example, for electronic devices and provisioned with effective heat dissipation abilities, are described herewith. The chassis component can be, for example, a part of a body or housing of the electronic device which may be in direct contact with a heat-generating component of the electronic device, such as a motherboard, a battery, and the like. According to an aspect, the chassis component is designed to function as a two-phase flow heat plate, such as a vapor chamber, without either affecting the form factor of the electronic device or of the chassis itself. In other words, even with the chassis component designed to operate as the two-phase flow heat plate, the overall size of the electronic device as well as the cross-sectional thickness of the chassis component remains unaffected.

In an example, the chassis component can include a flat body and a recess can be formed in a surface of the flat body. The recess can be formed in a way that it has a shoulder formed along an edge or boundary of the recess. In other words, the shoulder can be formed at the edge of the recess where the recess meets the flat body. For the chassis component to function as the two-phase flow heat plate, a working fluid can be disposed in the recess along with a mesh structure for capillary action for the movement of the working fluid within the recess. Further, recess can be sealed with a conductive cover by bonding the conductive cover to the flat body at the shoulder of the recess. Once sealed, the recess can be heated to vaporize the working fluid and form the working fluid therein, to form the two-phase flow heat plate in the chassis component.

Since the cross-section thickness of the chassis component has to be maintained unchanged, the effect on strength and durability of the chassis component due to formation of the recess is countered by integrally coupling the conductive cover at the shoulder of the recess, Such a design provides structural strength to the chassis component, for example, even when material has been removed from the chassis component. Therefore, the chassis component itself can facilitate in the removal of heat from the electronic device, thereby preventing use of any additional equipment which can otherwise unnecessarily affect the form factor of the electronic device.

The above aspects are further described in conjunction with the figures, and in associated description below. It should be noted that the description and figures merely illustrate principles of the present subject matter. Therefore, various arrangements that encompass the principles of the present subject matter, although not explicitly described or shown herein, may be devised from the description and are included within its scope. Additionally, the word “coupled” is used throughout for clarity of the description and can include either a direct connection or an indirect connection.

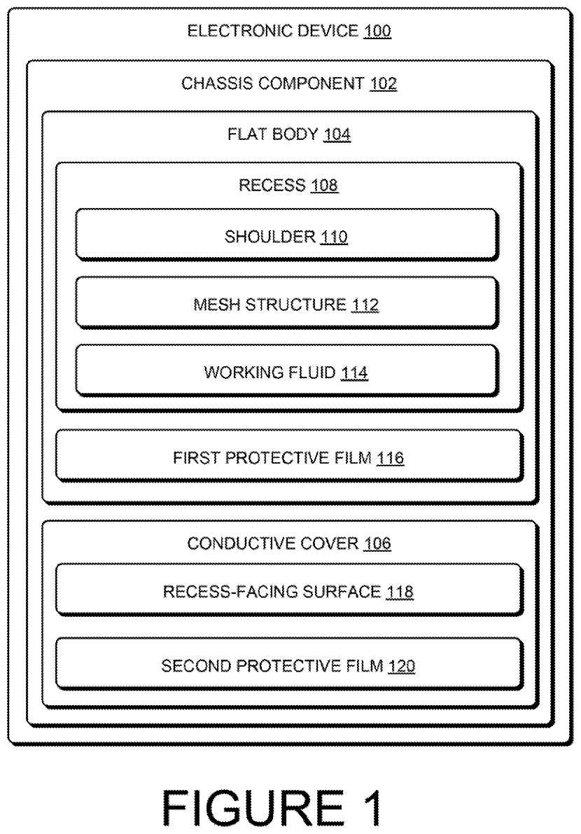

FIG. 1 illustrates a schematic of an electronic device 100 having a chassis component 102, in accordance with an example of the present subject matter. The electronic device 100 can include, for example, a laptop personal computer (PC), a desktop PC, a notebook PC, a mobile phone, a tablet PC, or a personal digital assistant (PDA). The chassis component 102 of the electronic device 100 may be designed to effectively cool the electronic device 100 during operation thereof. Accordingly, in said example, the chassis component 102 can include a flat body 104 and a conductive cover 106. The flat body 104 can have a recess 108 formed in a surface of the flat body 104 and the conductive cover 106 can cover the recess 108 to close the recess 108. In said example, the recess 108 can include a shoulder 110 formed along an edge of the recess 108 and the conductive cover 106 can be melded to the shoulder 110 to seal the recess 108. Further, the recess 108 can contain a mesh structure 112 and a working fluid 114 therein to form a two-phase flow heat plate in the chassis component. In addition, the recess 108 can be coated with a first protective film 116 and a recess-facing surface 118 of the conductive cover 106 is coated with a second protective film 120.

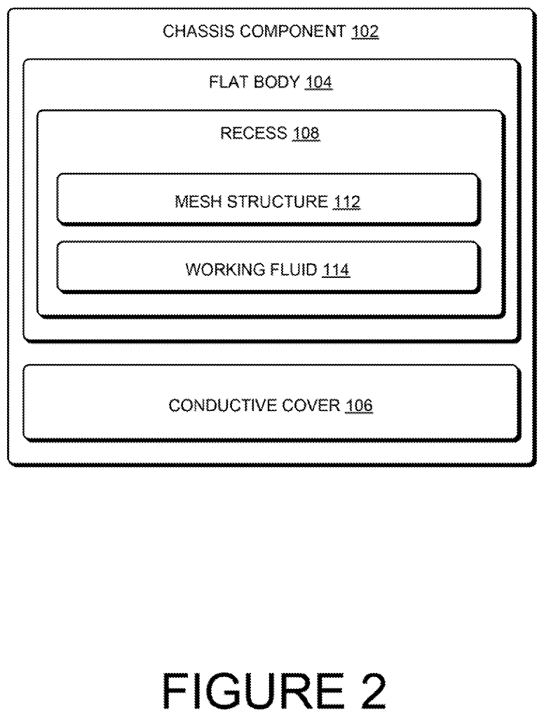

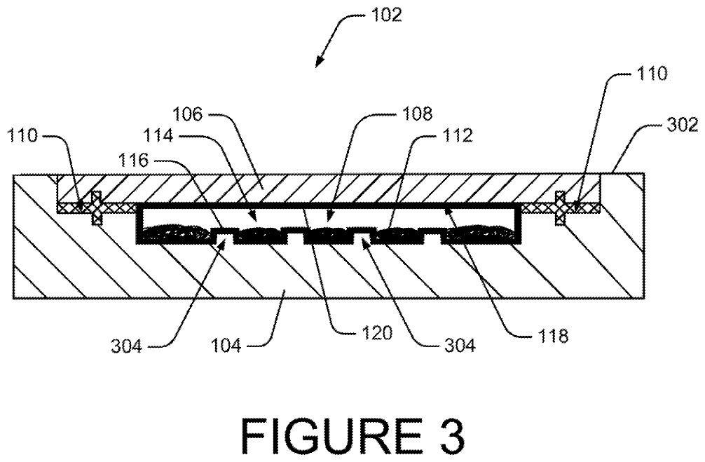

FIG. 2 illustrates a schematic of the chassis component 102, according to another example of the present subject matter. In the present example, the chassis component 102 can include the flat body 104 having the recess 108. The chassis component 102 can further include the conductive cover 106 which is bonded to the flat body 104 to cover and seal the recess 108 with the mesh structure 112 and the working fluid 114 container therein, such that the two-phase flow heat plate is formed in the chassis component. In other words, with such a construction of the chassis component 102, a portion of the chassis component 102, for instance, in which the recess 108 is formed, functions as the two-phase heat plate. The chassis component is discussed in further detail with reference to FIG. 3.

FIG. 3 illustrates a cross-sectional view of the chassis component 102 of the electronic device 100, according to an example of the present subject matter. As has been discussed above, the chassis component 102 can include the flat body 104 and the conductive cover 106 bonded to the flat body 104. As mentioned previously, the chassis component 102 can be designed for achieving effective cooling thereof and of surrounding components. For example, when deployed in the electronic device 100, various heat-generating components, such as a motherboard or a battery, may be positioned adjacent to or abutting to the chassis component 102 for dissipating the heat form the heat-generating components. Accordingly, the conductive cover 106 may be formed of a thermally conductive material to assist the dissipation of heat from the heat-generating components of the electronic device 100. In addition, in an example, the flat body 104 can also be formed of a thermally conductive material to allow effective heat dissipation. For instance, the flat body 104 can be made of aluminum and the conductive cover 106 can be made of copper.

The flat body 104 has a surface 302 in which the recess 108 is formed. In an example, the recess 108 can be etched into the surface 302. In another example, the surface 302 of the flat body 104 can be machined to form the recess 108. For example, an outline which substantially matches the conductive cover 106 is formed on the surface 302 and along the outline the surface is processed, for instance, etched or machined, to form the recess 108. In one case, the recess 108 can have a depth, measured from the surface 302, of about one-third of a cross-sectional thickness of the flat body 104. For instance, the cross-sectional thickness of the flat body 104 of the chassis component 102 can be about 0.7 millimeter (mm) and the depth of the recess 108 can be about 0.2 mm.

To enable the chassis component 102 to effectively dissipate heat, as mentioned previously, the chassis component 102 can be designed to function as a two-phase flow heat plate. Accordingly, the mesh structure 112 and the working fluid 114 can be positioned in the sealed recess 108. In an example, the working fluid can be water. During operation of the chassis component 102, for example, when deployed in the electronic device 100 along with the heat-generating components of the electronic device 100, the working fluid 114 can absorb heat from the heat-generating components and can change phase from liquid to vapor phase. For instance, the heat-generating components can abut the conductive cover 106 to absorb heat from such components, and the working fluid 114 can, in turn, absorb that heat from the conductive cover 106. The vaporized working fluid can then flow to a relatively cooler portion of the recess 108 where it can be cooled by dissipating heat, for instance, to a portion of the flat body 104 away from the heat-generating components. Accordingly, in that process, the working fluid 114 can change phase again to liquid phase, while the heat is radiated away from the chassis component 102. The working fluid 114 can then be directed back towards the part, of the recess 108 which is in the vicinity of the heat-generating components via the mesh structure 112. In said example, the mesh structure 112 can act as a capillary structure to direct the working fluid. Therefore, the working fluid 114, inside the sealed recess 108 and assisted by the mesh structure 112, can continuously undergo phase change between vapor and liquid, thereby undergoing the cycle of heat absorption and heat dissipation, to effectively cool the electronic device 100.

Further, the chassis component 102 of the present subject matter can have provisions for enhancing strength thereof, for example, to counter the effects of removal of material for forming the recess 108. Accordingly, in one example as discussed above, while forming the recess 108, the recess can be formed as having the shoulder 110. The shoulder 110 can be formed along a boundary of the recess 108. The conductive cover 106 can be bonded to the flat body 104 at the shoulder 110 of the recess 108.

In one case, the conductive cover 106 can be bonded to the flat body 104 using bonding glue to prevent direct contact between the conductive cover 106 and the flat body 104, for instance, the shoulder 110 of the flat body 104. For instance, such a mode of bonding the conductive cover 106 and the flat body 104 can be used where a material of the flat body 104 and that of the conductive cover 106 may not be compatible with each other and may, for example, react with each other causing damage to the chassis component 102. In another example, for instance, where the materials of the flat body 104 and the conductive cover 106 are compatible, the conductive cover 106 may be bonded to the flat body 104 by other modes of bonding, such as welding. In both the above examples, for instance, the bonding is so done that the bonding does not adversely affect the heat dissipation capability of the chassis component 102. Therefore, in the former example where the conductive cover 106 is bonded to the flat body 104 using a bonding glue, the bonding glue may be thermally conductive in nature, and can be, for instance, a metal-based glue or can include fragments of a thermally conductive material.

The provision of the bonding the conductive cover 106 at the shoulder 110 of the recess 108 provides a degree of integrity to the chassis component 102 and enhances the strength and durability of the chassis component 102. In another example, alternately or additionally to the previous example, the recess 108 can have a support structure 304 formed therein which further enhance the strength of the chassis component 102. For instance, the support structure 304 can be formed as a plurality of support pillars or as a plurality of ribs.

Further, in an example, the recess 108 can be coated with protective film, such as the first protective film 116 to prevent the working fluid 114 from coming into contact with the recess 108. Similarly, the recess-facing surface 118 of the conductive cover 106 can also be coated with a protective film, such as the second protective film 120, so that the working fluid 114 does not come in contact with the conductive cover 106, For example, the working fluid 114, in certain cases, may be such that it may have a corrosive effect on the recess 108 as well as the conductive cover 106, in the absence of the protective films 116 and 120. Further, to ensure that the protective films 116 and 120 do not hinder the heat-dissipation ability of the chassis component 102, either of the first protective film 116 and the second protective film 120, or both may be thermally conductive.

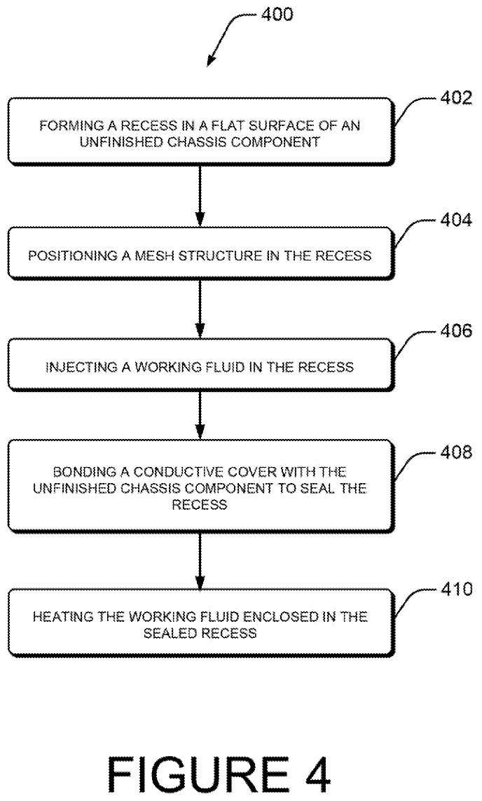

FIG. 4 illustrates a method 400 of manufacturing the chassis component 102 for the electronic device 100. The order in which the blocks in the method 400 is described is not intended to be construed as a limitation, and any number of the described blocks can be combined in any order to employ the method 400, or an alternative flow diagram. Additionally, individual blocks may be deleted from the method 400 without departing from the scope of the subject matter described herein.

Referring to method 400, at block 402, the recess 108 is formed in a flat surface, such as the surface 302, of an unfinished chassis component. In an example, the unfinished chassis component can be an unfinished flat body 104 which can be, for instance, a part of the chassis of the electronic device 100. For example, the unfinished chassis component, or the unfinished flat body 104, can be a bottom chassis of a laptop PC or a notebook PC, or a rear cover of a tablet PC, without the two-phase flow heat plate formed therein. In an example, the recess 108 can be formed by etching on the surface 302. In another example, the surface 302 of the flat body 104 can be machined to form the recess 108.

Further, at block 404, the mesh structure 112 is positioned in the in the recess 108. In an example, the mesh structure 112 can be formed by micro-trench machining or copper-powder sintering.

At block 406, the working fluid 114 can be injected in the recess 108. For instance, the working fluid 114 can be water.

At block 408, the conductive cover 106 can be bonded with the unfinished chassis component, for instance, the unfinished flat body 104, to seal the recess 108. In one example, where a material of the unfinished chassis component and that of the conductive cover 106 may not be compatible with each other, the conductive cover 106 can be glued to the unfinished chassis component using bonding glue. The bonding glue can prevent direct contact between the conductive cover 106 and the unfinished chassis component. In another example, for instance, where the materials of the flat body 104 and the conductive cover 106 are compatible, the conductive cover 106 may be bonded to the flat body 104 by other modes of bonding, such as welding.

For instance, a top fixture and a bottom fixture may be used for setting the conductive cover 106 on top of the recess 108 to close the recess 108. In said example, the unfinished chassis component, such as the flat body 104, can be coupled to the bottom fixture and the conductive cover 106 can be coupled to the top fixture, and the top and bottom fixtures can be moved relative to each other to couple bond the conductive cover 106 to the unfinished chassis component.

At block 410, the working fluid 114 enclosed in the sealed recess 108 can be heated. For instance, the enclosed working fluid 114 can be heated to achieve a predetermined level of vacuum inside the sealed recess 108, such that the chassis component 102 so formed can function as the two-phase flow heat plate. In the above example where the flat body 104 is coupled to the bottom fixture, the bottom fixture can be provided with a heating mechanism, such as a heating element, which can heat the working fluid 114 enclosed in the sealed recess 108, for example, to vaporize the working fluid 114. A portion of the chassis component 102 so formed, for example, in which the recess 108 with the mesh structure 112 and the working fluid 114 sealed therein, can function as the two-phase heat plate and can enable the chassis component 102 to effectively dissipate heat.

Although aspects of the chassis component 102 for the electronic device 100 have been described in a language specific to structural features and/or methods, it is to be understood that the subject matter is not limited to the features or methods described. Rather, the features and methods are disclosed as examples of the chassis component 102 for the electronic device 100.

I/We claim:

1. A chassis component comprising:
a flat body having a recess formed in a surface thereof, the recess including a mesh structure and a working fluid disposed therein; and
a conductive cover bonded to the flat body to seal the recess;
wherein the recess sealed with the mesh structure and the working fluid therein forms a two-phase flow heat plate in the chassis component.

2. The chassis component as claimed in claim 1, wherein the conductive cover is bonded to the flat body using bonding glue to prevent direct contact between the conductive cover and the flat body.

3. The chassis component as claimed in claim 1, wherein at least one of the recess and a recess-facing surface of the conductive cover are coated with a protective film to prevent contact with the working fluid.

4. The chassis component as claimed in herein the protective film is thermally conductive.

5. The chassis component as claimed in claim 1, wherein the recess has a depth of about one-third of a cross-sectional thickness of the flat body.

6. The chassis component as claimed in claim 1, wherein the recess comprises a shoulder formed along a boundary of the recess, the conductive cover being bonded at the shoulder of the recess.

7. The chassis component as claimed in claim 1, wherein the recess further comprises a support structure formed therein.

8. A method of manufacturing a chassis component for an electronic device, the method comprising:
forming a recess in a flat surface of an unfinished chassis component;
positioning a mesh structure in the recess;
injecting a working fluid in the recess;
bonding a conductive cover with the unfinished chassis component to seal the recess; and
heating the working fluid enclosed in the sealed recess.

9. The method as claimed in claim 8, wherein the forming the recess comprises coating the recess with a protective coating, the protective coating being thermally conductive.

10. The method as claimed in claim 8, the bonding the conductive cover comprises coating a recess-facing surface of the conductive cover with a protective coating, the protective coating being thermally conductive.

11. The method as claimed in claim 8, wherein the forming the recess comprises forming a shoulder along an edge of the recess, the conductive cover being integrally attached to the unfinished chassis component at the shoulder.

12. The method as claimed in claim 8, wherein the bonding the conductive cover comprises gluing the conductive cover to the unfinished chassis component.

13. An electronic device comprising:
a chassis component comprising:
a flat body having a recess formed in a surface thereof, wherein the recess comprises a shoulder formed along an edge of the recess, the recess being coated with a first protective film; and
a conductive cover melded to the shoulder of the recess to seal the recess, wherein a recess-facing surface of the conductive cover is coated with a second protective film;
wherein the recess is sealed with a mesh structure and a working fluid contained therein to form a two-phase flow heat plate in the chassis component.

14. The electronic device as claimed in claim 13, wherein the first protective film and the second protective film are thermally conductive.

15. The electronic device as claimed in claim 13, wherein the recess further comprises a support structure formed therein.
